(19) United States
(12) Patent Application Publication
(10) Pub. No.: US 2008/0135279 A1
(43) Pub. Date: Jun. 12, 2008

(54) Printed wiring board having plural solder resist layers and method for production thereof

(75) Inventor: Kiminori Ishido, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, kawasaki (JP)

(21) Appl. No.: 11/984,037

(22) Filed: Nov. 13, 2007

(30) Foreign Application Priority Data
Dec. 11, 2006 (JP) 2006-333544

(51) Int. Cl. H05K 1/03; B05C 17/06

(52) U.S. Cl. 174/255; 29/846

(57) ABSTRACT

A printed wiring board includes: a substrate main body; a solder resist layer provided on the substrate main body and having a first opening in which a part of the solder bump is formed; and a solder resist layer provided on the solder resist layer and having a second opening through which the solder bump is formed. The shape of the second opening is non-analogous to the shape of the first opening when viewed as plane-wise.

### BACKGROUND OF THE INVENTION

1. Field of the Invention

The present invention relates to a printed wiring board and a method for production thereof.

2. Description of Related Art

As the speed has been enhanced and the number of pins has been increased for semiconductor devices, the proportion of application of C4 (Controlled Collapse Chip Connection) flip chip mounting has been increased among a various kinds of mounting methods. The C4 is a construction method of mounting a pad on a substrate with a pad on a chip by a solder bump. Furthermore, in this connection, for solders used in a bump material, demands for lead-free solders have grown in terms of environmental conservation. When the lead-free solder is used for both a wafer bump and a preliminary solder on a printed wiring board, the mounting temperature is high, and the entire bump is remelted at the time of reflow when a BGA solder ball is attached or when a semiconductor device is mounted on a board, as compared to a case where an eutectic preliminary solder formed on a mounting pad of the printed wiring board is melted and jointed to the wafer bump of high-temperature soldering to perform mounting. At this time, a solder resist which is a surface layer protecting film of the printed wiring board is required to have a function as a solder dam to block an escaping solder for preventing a short failure between bumps.

Japanese Patent Laid-Open No. 2006-202881 describes a printed wiring board comprising such a solder resist. FIGS. 5A and 5B are a sectional view and a plan view, respectively, showing an outlined configuration of the printed wiring board described in the document. On the surface layer of a substrate main body 112 is formed a solder resist layer 131 having an opening at a position corresponding to a mounting pad 120a, and thereon is formed a solder resist layer 132 having an opening having a diameter greater than that of the opening of the solder resist layer 131. An inner space of the opening of the solder resist layer 131 is filled with a solder paste up to a height equivalent to that of the solder resist layer 132, and then made to reflow to form a solder bump 134.

Japanese Patent Laid-Open No. 9-293758 discloses that a non-conductive partition is provided between electrodes of a semiconductor carrier.

However, in a printed wiring board comprising a solder resist, shown in FIGS. 5A and 5B, an opening of a solder resist layer 131 and an opening of a solder resist layer 132 are formed concentrically when viewed as plane-wise. Thus, a gap (grove) having a substantially constant width emerges between the solder resist layer 132 and a solder bump 134. In such a mounting pad structure, a flux used at the time of forming the solder bump 134 and mounting the C4 flip chip enters the above gap and tends to remain due to a degradation in washing characteristic. This becomes a factor of hindering adhesiveness between the printed wiring board and an underfill.

### SUMMARY OF THE INVENTION

A printed wiring board according to one exemplary aspect of the present invention includes a substrate main body; a first solder resist layer provided on the substrate main body and having a first opening in which a part of the solder bump is buried; and a second solder resist layer provided on the first solder resist layer and having a second opening through which the solder bump extends. The shape of the second opening is non-analogous to the shape of the first opening when viewed as plane-wise.

Furthermore, a method for production of a printed wiring board according to one exemplary aspect of the present invention includes forming on a substrate main body a first solder resist layer having a first opening in which a part of the solder bump is buried and forming on the first solder resist layer a second solder resist layer having a second opening through which the solder bump extends. The second opening is formed so as to have a shape which is non-analogous to the shape of the first opening when viewed as plane-wise.

In the aspects, the shape of the opening (second opening) of the second solder resist layer is non-analogous to the opening (first opening) of the first solder resist layer when viewed as plane-wise. Consequently, emergence of a gap having a substantially constant width between the second solder resist layer and the solder bump can be prevented. Thus, a phenomenon is hard to occur in which a flux remains on the surface of the first solder resist layer. Therefore, high adhesiveness can be obtained between the printed wiring board and an underfill.

According to the aspects of the present invention, there are provided a printed wiring board capable of obtaining high adhesiveness between itself and an underfill and a method for production thereof.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a sectional view showing an outlined configuration of a printed wiring board according the first embodiment of the present invention,

FIG. 2 is a plan view showing an outlined configuration of the printed wiring board according the first embodiment of the present invention,

FIGS. 3A-3D are process charts showing one embodiment of a method for production of the printed wiring board according to the present invention,

FIG. 4 is a plan view showing an outlined configuration of the printed wiring board according to the second embodiment of the present invention, and

FIGS. 5A and 5B are a sectional view and a plan view each showing an outlined configuration of the conventional printed wiring board.

### DETAILED DESCRIPTION OF THE EXEMPLARY EMBODIMENT

Exemplary embodiments of a printed wiring board according to the present invention will be described in detail below. In the explanations of the drawings, same symbols are given to same elements to avoid redundant explanations.

### First Embodiment

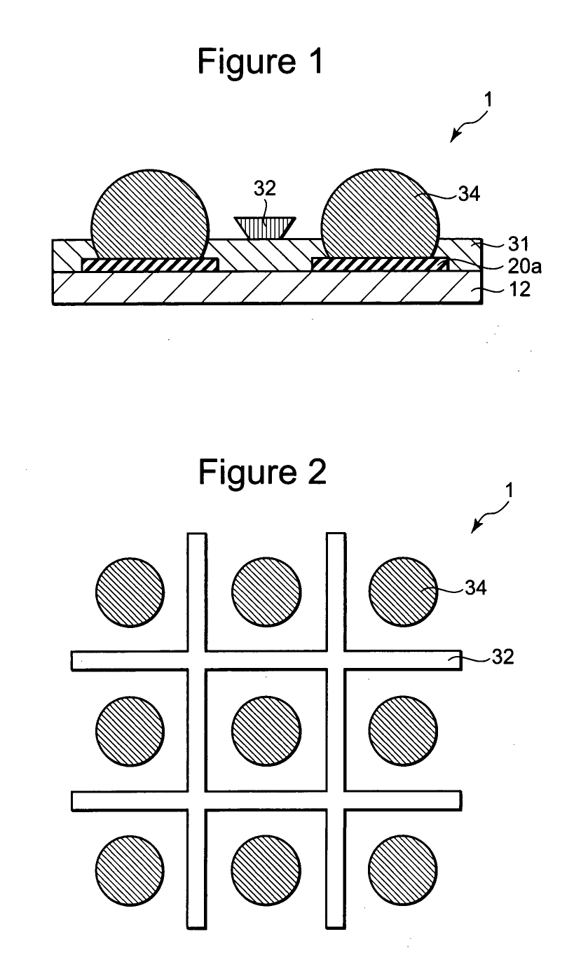

FIGS. 1 and 2 are a sectional view and a plan view, respectively, showing an outlined configuration of a printed wiring board according to the first embodiment of the present invention. A printed wiring board 1 is a printed wiring board on which electronic components are mounted via a solder bump 34, comprising a substrate main body 12, a solder resist layer 31 (first solder resist layer) provided on the substrate main body 12 and having a first opening in which a part of the solder bump 34 is buried, and a solder resist layer 32 (second solder resist layer) provided on the solder resist layer 31 and having a second opening through which the solder pump 34 extends. Here, the shape of the second opening is non-analogous, non-similar, or non-homothetic to the shape of the first opening when viewed as plane-wise. In this embodiment, the shapes of the first and second openings are circular and rectangular, respectively, when viewed as plane-wise. The first opening may be geometrically same as the second opening.

More specifically, in the structure of the printed wiring board 1 subjected to C4 flip chip mounting by the solder bump 34, on the flip chip mounting surface of the surface layer of the substrate main body 12 is formed the solder resist layer 31 covering a wiring and forming an SMD (Solder Mask Define) structure by providing an opening on a mounting pad 20a. The SMD structure is a structure that the shape or area of the mounting pad is defined by the opening or radius of the solder resist layer 31. The mounting pad 20a has a round shape from the plane or top view. Thereon, a solder dam by the solder resist layer 32 is formed between adjacent solder bumps 34. The height of the solder resist layer 32 is smaller than the height of the solder bump 34. The height of the solder resist layer 32 is preferably in a range of 5 μm or more and 35 μm or less.

Furthermore, the solder resist layer 32 has an undercut shape. Namely, the lower surface of the solder resist layer 32 (surface on the solder resist layer 31 side) has an area smaller than the upper surface of the solder resist layer 32 (surface on a side opposite to the solder resist layer 31). In this way, an angle formed by the side surface of the solder resist layer 32 with respect to the solder resist layer 31 is less than 90°.

As shown in FIG. 2, the solder bump 34 is arranged in the form of a tetragonal lattice. Accordingly, the mounting pad 20a and the first opening below the solder bump 34 are also arranged in the form of a tetragonal lattice. Between solder bumps 34 is formed the linear solder resist layer 32 so as to form a tetragonal lattice. Each solder bump 34 is surrounded by this solder resist layer 32. The top line width (line width of upper surface) of the solder resist layer 32 is, for example, about 5 μm to 60 μm. The solder resist layer 32 has an undercut shape as described above, and for the dimension of the undercut shape, a value obtained by subtracting the bottom line width (line width of lower surface) from the top line width is preferably 1 μm or more.

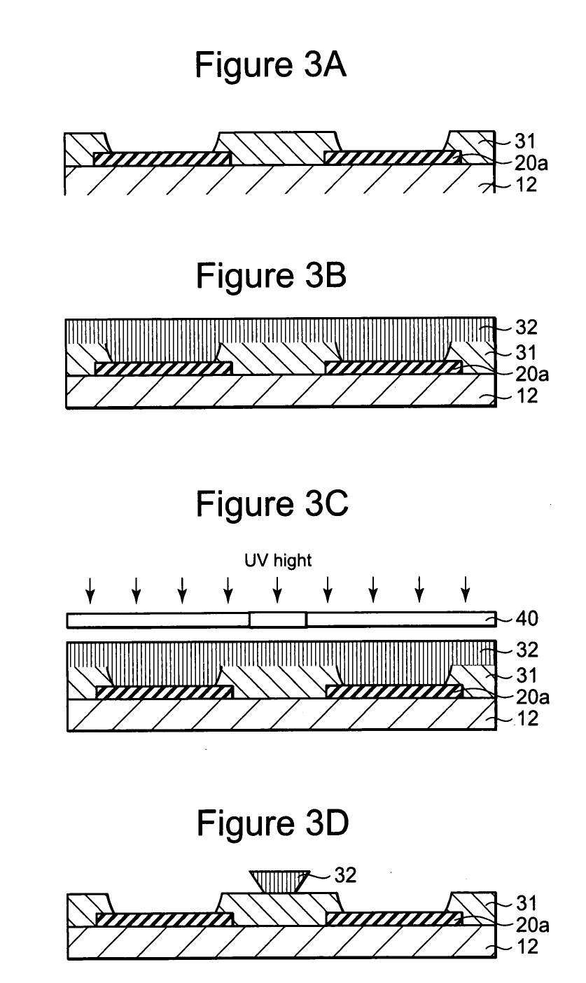

As one embodiment of the method for production of the printed wiring board according to the present invention, one example of the method for production of the printed wiring board 1 will be described with reference to FIGS. 3A to 3D. First, the solder resist layer 31 is patterned on the substrate main body 12 having a conductive pattern formed thereon as a wiring and mounting pad 20a, and cured (FIG. 3A). Next, the liquid and alkali-development type solder resist layer 32 is coated on the entire surface so as to have a thickness of 5 to 35 μm. Thereafter, the solvent is removed, and the product is dried at 70 to 90° C. for 15 to 45 minutes so as to be rendered tack-free (FIG. 3B). For the solder resist layer 32, an ink composition with importance not placed on internal curability in the blended ratio of a photo-initiator and its adjuvant is preferably used.

Next, using a mask 40, UV light of 100 to 700 mJ/cm² is applied selectively to areas to be cured (FIG. 3C). Subsequently, spray development is carried under a pressure of 0.5 to 2 kg/cm² using a 0.5 to 1.5 wt % aqueous sodium carbonate solution. The development time is set so as to be two to five times as long as a break point. The break point herein is defined as a time taken for the unexposed solder resist layer 32 to be completely dissolved. Thereafter, UV light of 0.5 to 2 J/cm² is applied and a heat treatment is carried out at 140 to 170° C. for 1 to 2 hours to obtain the printed wiring board 1 comprising the solder resist layer 32 having an undercut longitudinal shape arid formed into a desired pattern (FIG. 3D).

Thus, in this embodiment, the step of forming the solder resist layer 32 comprises the steps of: treating the photographic development type solder resist layer 32 so as to be rendered tack-free; exposing the solder resist layer 32 after the treatment and carrying out development for a time in a range of two times or more and five times or less as long as the break point; and curing the solder resist layer after the development.

The effect of this embodiment will be described. In this embodiment, the shape of the opening (second opening) of the solder resist layer 32 is non-analogous to the shape of the opening (first opening) of the solder resist layer 31 when viewed as plane-wise. For example, the opening of the solder resist layer 31 is circular and the opening of the solder resist layer 32 may be an other than circular. For example, the opening of the solder resist layer 32 may be oval, polygon, in additional to the rectangular as described before. Consequently, emergence of a gap having a substantially constant width between the solder resist layer 32 and the solder bump 34 can be prevented. The solder resist layer 32 produces a turbulent flow of a washing liquid. Thus, a phenomenon is hard to occur in which a flux used at the time of forming the solder bump 34 and at the time of C4 flip chip mounting remains on the surface of the solder resist layer 31. The flux is an agent for coating a cupper pad which is conducted soldering. The flux removes an oxide on the cupper pad. Therefore, high adhesiveness can be obtained between the printed wiring board 1 and the underfill.

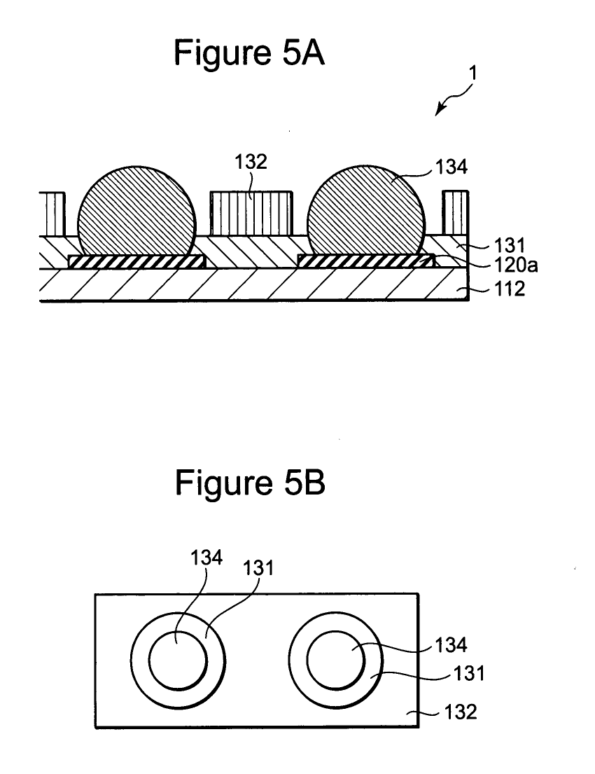

In contrast to this, in the printed wiring board shown in FIGS. 5(a) and 5(b), the shape of an opening of a solder resist layer 131 is analogous to the shape of an opening of a solder resist layer 132. The solder resist layer 132 is the perfect circle from the top view. Consequently, a gap having a substantially constant width emerges between the solder resist layer 132 and a solder bumping 134. So, as described above, the washing characteristic for a flux is degraded, so that the flux remains on the surface of the solder resist layer 131.

Moreover, the solder bump 134 is formed so as to have a height almost equivalent to that of the solder resist layer 132, and therefore the above gap is so deep that the flux washing characteristic is further degraded. Furthermore, air tends to be trapped in the above gap at the time of injecting an underfill, which is also a factor of promoting emergence of an underfill void. According to this embodiment, such a problem can be resolved.

Further, in this embodiment, a situation can be prevented in which a solder flowing out of a bump runs over the solder resist layer 32 to contact the adjacent solder bump 34 since solder resist layer 32 has an undercut shape. Further, owing to the anchor effect, adhesiveness between the printed wiring board 1 and the underfill is further improved.

### Second Embodiment

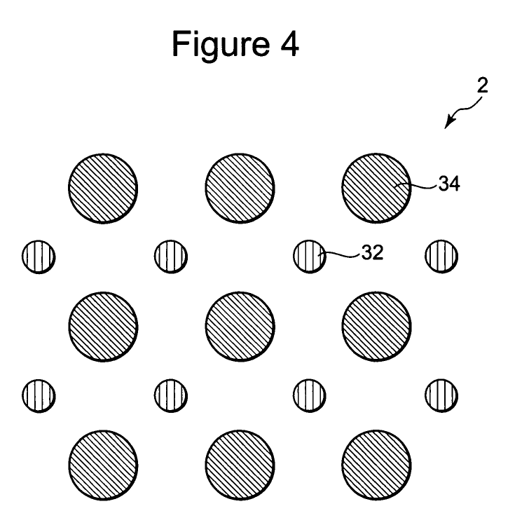

FIG. 4 is a plan view showing an outlined configuration of a printed wiring board according to the second embodiment of the present invention. In this connection, the structure of the section of a printed wiring board 2 is similar to that shown in FIG. 1. An opening (first opening) of a solder resist layer 31 is provided on a mounting pad 20a arranged in the form of a tetragonal lattice. In this embodiment, a solder resist layer 32 is formed as a dot pattern. Namely, the solder resist layer 32 is columnar. Its diameter is, for example, about 5 to 160 μm. In this embodiment, the solder resist layer 32 also has an undercut shape. Therefore, the solder resist layer 32 is tapered with the diameter gradually decreasing as going toward the solder resist layer 31. Furthermore, the solder resist layer 32 is arranged in the form of zigzag lattice with the first opening when viewed as plane-wise. Other aspects of the configuration and the production method for the printed wiring board 2 are similar to those for the printed wiring board 1.

In this embodiment, the columnar solder resist layer 32 is arranged in the form of a zigzag lattice with the first opening. In this way, when washing out a flux used at the time of forming a solder bump 34 and at the time of C4 flip chip mounting, the flow rate of a washing liquid can be increased and a liquid flow can be changed into a turbulent flow to improve the washing characteristic.

Methods for retaining and improving adhesiveness between the printed wiring board and the underfill include preventing the flux described above from remaining on the coated surface of the underfill and enhancing the anchor effect of the adhesion interface. In this embodiment, any of these methods can be technically reinforced. Other effects of the printed wiring board 2 are similar to those of the printed wiring board 1.

The printed wiring board and the method for production thereof according to the present invention are not limited to the embodiments described above, but various alterations are possible. For example, in the above embodiments, the example has been shown in which the mounting pad 20a is arranged in the form of a tetragonal lattice, but the mounting pad 20a may be arranged in the form of a zigzag lattice.

Further, it is noted that, Applicant's intent is to encompass equivalents of all claim elements, even if amended later during prosecution

What is claimed is:

1. A printed wiring board, comprising:
a substrate main body:
a first solder resist layer which is provided on the substrate main body and comprises a first opening in which a part of the solder bump is buried; and
a second solder resist layer which is provided on the first solder resist layer and comprises a second opening through which the solder bump extends,
wherein a shape of the second opening is non-analogous to a shape of the first opening when viewed as plane-wise.

2. The printed wiring board according to claim 1, wherein said second solder resist layer comprises a first surface attached to the first solder resist layer and a second surface opposed to said first surface, said first surface having an area smaller than an area of said second surface.

3. The printed wiring board according to claim 1, wherein an angle of a side surface of the second solder resist layer with respect to the first solder resist layer is less than 90°.

4. The printed wiring board according to claim 1, wherein the shapes of the first and second openings are circular and rectangular, respectively, when viewed plane-wise.

5. The printed wiring board according to claim 1, wherein the second solder resist layer is columnar.

6. The printed wiring board according to claim 5, wherein the second solder resist layer is arranged in a form of a zigzag lattice with the first opening when viewed plane-wise.

7. The printed wiring board according to claim 1, wherein the thickness of the second solder resist layer is in a range of 5 μm or more and 35 μm or less.

8. The printed wiring board according to claim 1, wherein the first opening is geometrically same as said second opening.

9. A method of forming a printed wiring board, comprising:
forming, on a substrate main body, a first solder resist layer including a first opening in which a part of a solder bump is buried; and
forming, on the first solder resist layer, a second solder resist layer containing a second opening through which the solder bump extends,
wherein the second opening is formed so as to have a shape which is non-analogous to a shape of the first opening when viewed plane-wise.

10. The method according to claim 9, wherein said forming the second solder resist layer comprises:
treating the second solder resist layer of a photographic development type so as to be rendered tack-free;
exposing the second solder resist layer after treatment and carrying out development for a development time in a range of two times or more and five times or less as long as a break point; and
curing the second solder resist layer after the development.

11. A printed wiring board, comprising:
a substrate main body:
a first solder resist layer which is provided on the substrate main body and comprises a first opening to form a solder bump therein; and
a second solder resist layer which is provided on the first solder resist layer and comprises a second opening to form the solder bump therein, said second opening having an other than circular structure such that the distance between an edge of said first opening and an edge of said second opening varies.

12. The printed wiring board as claimed in claim 11, wherein said second opening has rectangular shape.

13. The printed wiring board as claimed in claim 11, wherein said second opening has a shape so that said second solder resist layer constitutes a structure including a plurality of column.

14. The printed wiring board as claimed in claim 11, wherein said second opening has a polygonal shape.

15. The printed wiring board as claimed in claim 11, wherein said second opening has an oval shape.

16. The printed wiring board as claimed in claim 11, wherein said second solder resist layer comprises a first surface attached to the first solder resist layer and a second surface opposed to said first surface, said first surface having an area smaller than an area of said second surface.
